(19) United States
(12) Patent Application Publication
(10) Pub. No.: US 2019/0006305 A1
(43) Pub. Date: Jan. 3, 2019

(54) SEMICONDUCTOR PACKAGE STRUCTURE AND MANUFACTURING METHOD THEREOF

(71) Applicant: Powertech Technology Inc., Hsinchu County (TW)

(72) Inventor: Kun-Yung Huang, Hsinchu County (TW)

(73) Assignee: Powertech Technology Inc., Hsinchu County (TW)

(21) Appl. No.: 15/636,657

(22) Filed: Jun. 29, 2017

(51) Int. Cl. H01L 23/00; H01L 23/522; H01L 21/768

(52) U.S. Cl. CPC H01L 24/14; H01L 23/5226; H01L 2924/3511; H01L 24/83; H01L 21/76877

(57) ABSTRACT

A manufacturing method of a semiconductor package structure is provided. The method includes the following steps. A first redistribution layer is formed on a first surface of a semiconductor substrate. A plurality of through holes and an opening are formed on the semiconductor substrate. A chip is disposed in the opening of the semiconductor substrate. A conductive through via is formed in the through holes to electrically connect the first redistribution layer. A second redistribution layer is formed on a second surface of the semiconductor substrate opposite to the first surface to electrically connect the chip. The second redistribution layer is electrically connected to the first redistribution layer by the conductive through via. A plurality of conductive structures are formed on the second redistribution layer. A semiconductor package structure is also provided.

### BACKGROUND OF THE INVENTION

### Field of Invention

The present disclosure relates to a package structure manufacturing method, and more particularly, to a manufacturing method of semiconductor package structure.

### Description of Related Art

In certain categories of conventional packaging technologies, such as fan-out wafer level packaging (FO-WLP), a chip is encapsulated by a molding compound using a molding process. However, due to materials difference between the molding compound and the chip, a warpage issue may be generated during the manufacturing process of the semiconductor package structures. Therefore, development of the manufacturing process to avoid the warpage issue has become an important topic in the field.

### SUMMARY OF THE INVENTION

The disclosure provides a semiconductor package structure and a manufacturing method thereof, which avoids generating the warpage issue by omitting the conventional molding process and achieves the process simplicity.

The disclosure provides a manufacturing method of a semiconductor package structure. The method includes the following steps. A first redistribution layer is formed on a first surface of a semiconductor substrate. A plurality of through holes and an opening are formed on the semiconductor substrate. A chip is disposed in the opening of the semiconductor substrate. A conductive through via is formed in the through holes of the semiconductor substrate to electrically connect the first redistribution layer. A second redistribution layer is formed on a second surface of the semiconductor substrate opposite to the first surface to electrically connect the chip. The second redistribution layer is electrically connected to the first redistribution layer by the conductive through via. A plurality of conductive structures are formed on the second redistribution layer.

The disclosure provides a provides a semiconductor package structure including a semiconductor substrate, a chip, a first redistribution layer, a second redistribution layer, a conductive through via and a plurality of the conductive structures. The semiconductor substrate includes a first surface and a second surface opposite to the first surface. The semiconductor substrate includes a plurality of through holes and an opening penetrating through the semiconductor substrate. The chip is disposed in the opening of the semiconductor substrate. The first redistribution layer is disposed on the first surface of the semiconductor substrate. The second redistribution layer is disposed on the second surface of the semiconductor substrate. The second redistribution layer is electrically connected to the chip. The conductive through via is disposed in the through holes of the semiconductor substrate. The first redistribution layer is electrically connected to the second redistribution layer by the conductive through via. The conductive structures are disposed on the second redistribution layer.

Based on the above, the chip is disposed in the opening of the semiconductor substrate such that the semiconductor substrate may serve as the encapsulant to protect the chip. As such, the conventional molding process is omitted and the warpage issue may be eliminated. In addition, the conductive through via formed in the through holes may serve as the conductive path between the first redistribution layer and the second redistribution layer. Therefore, miniaturizing the semiconductor package structure while maintaining the process simplicity is achieved.

To make the above features and advantages of the present disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A to FIG. 1J are schematic cross-sectional views illustrating a manufacturing method of a semiconductor package structure according to an embodiment of the disclosure.

FIG. 2 is schematic cross-sectional view illustrating after forming the through holes and the opening on the semiconductor substrate according to an embodiment of the disclosure.

### DESCRIPTION OF EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

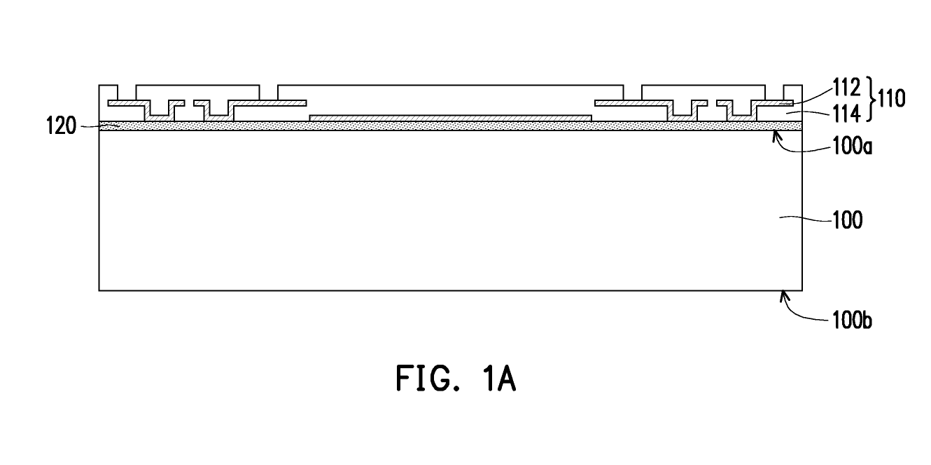

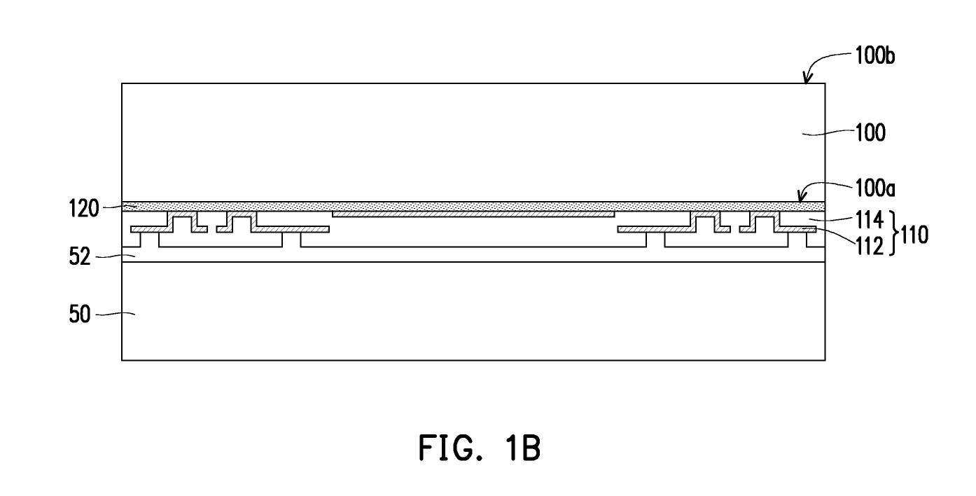

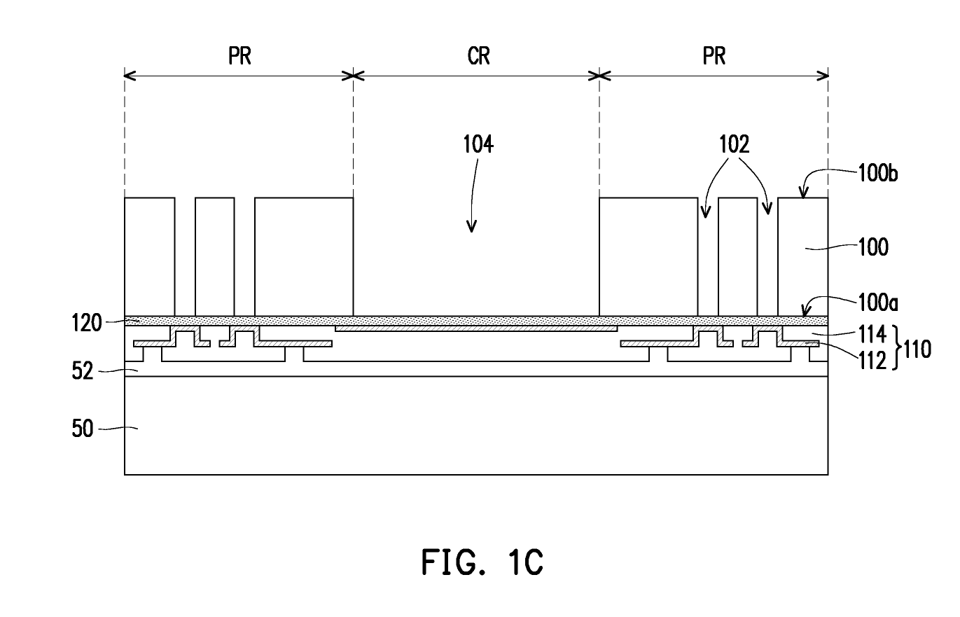

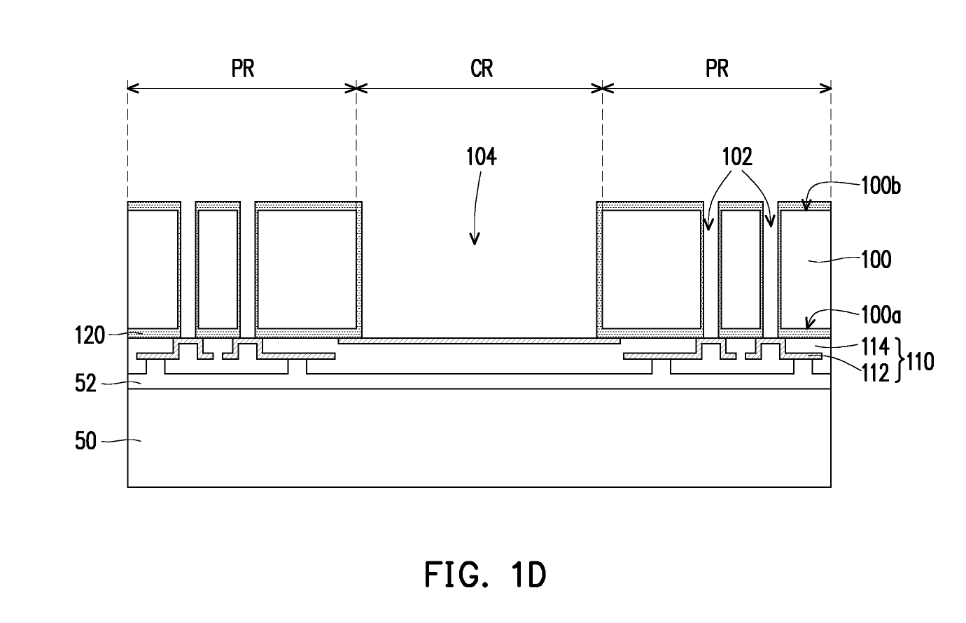

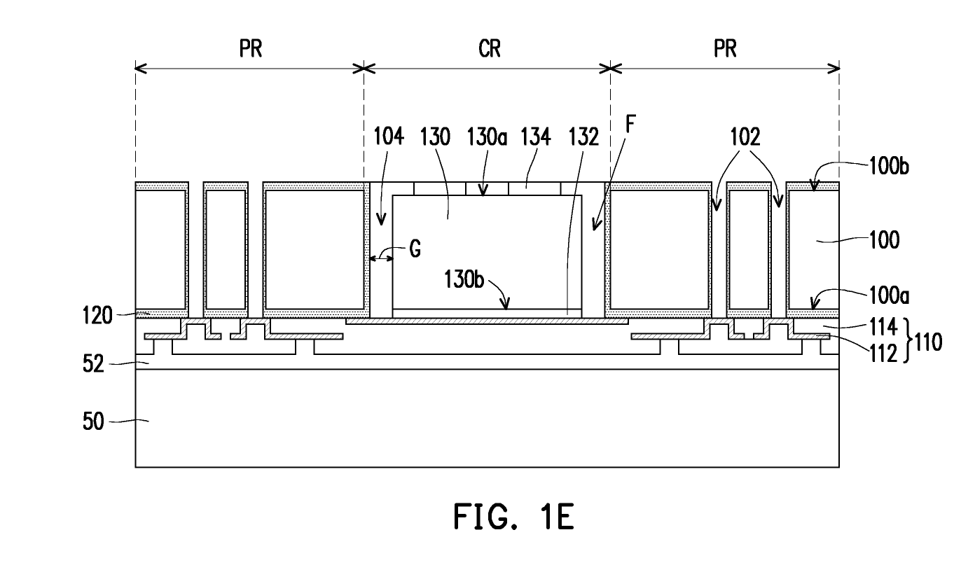

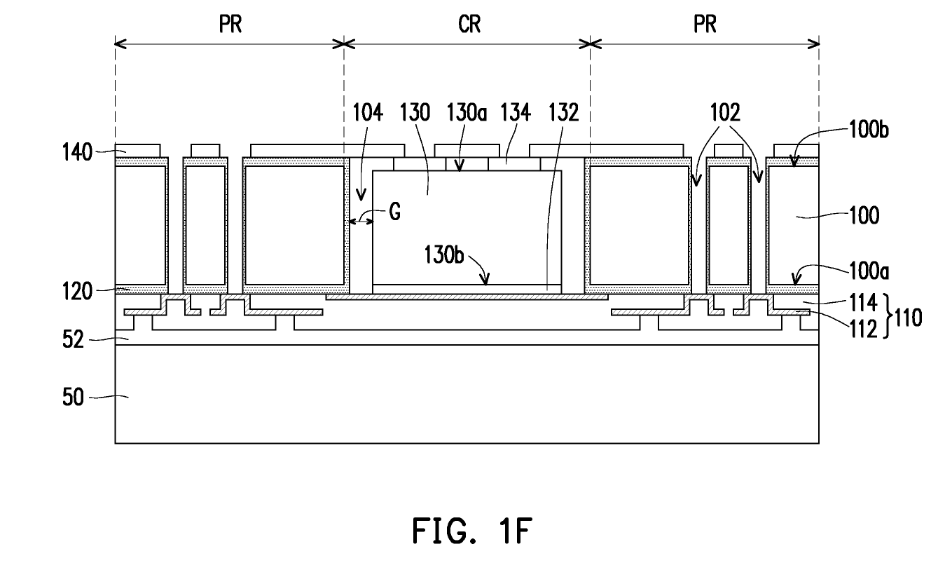

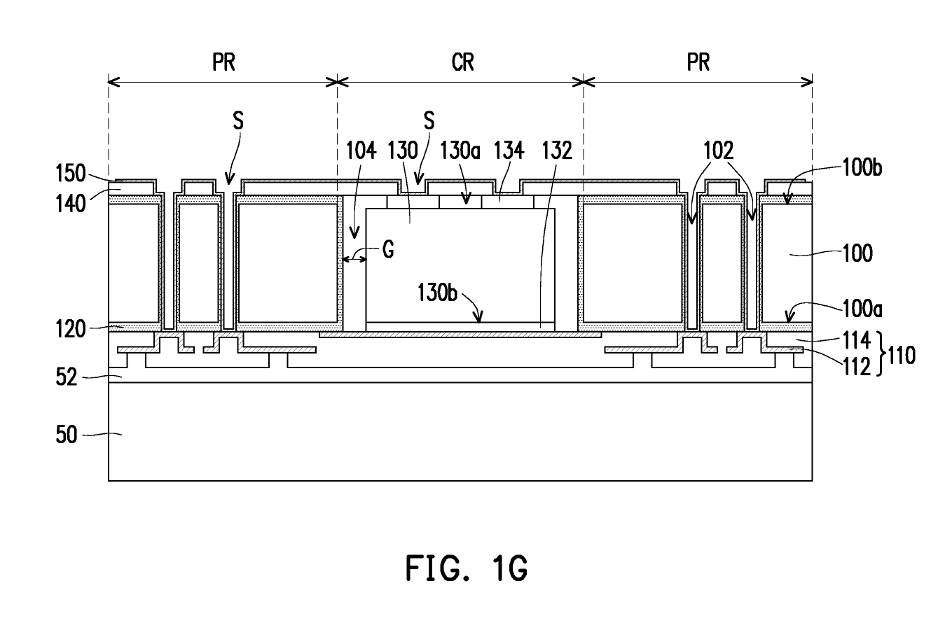

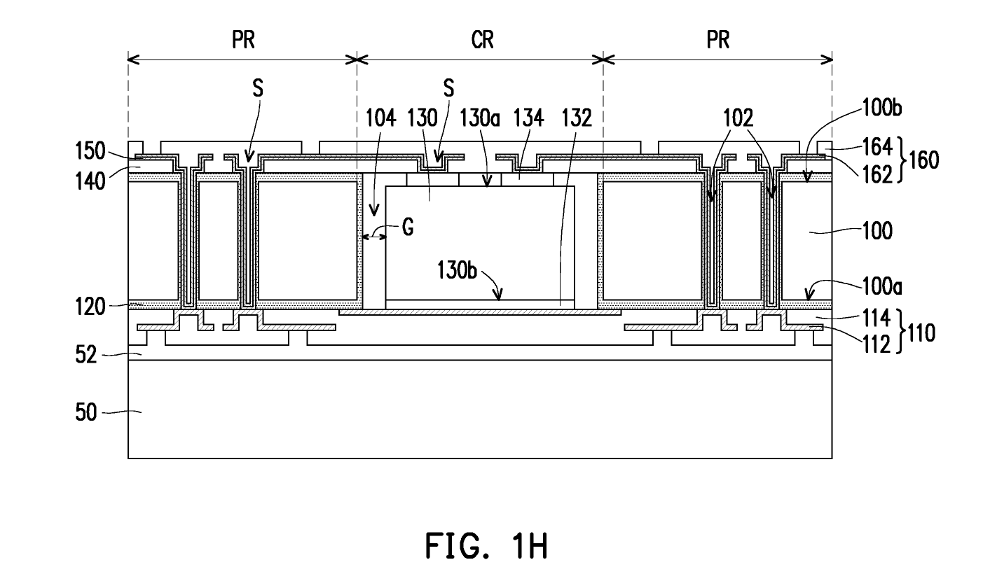

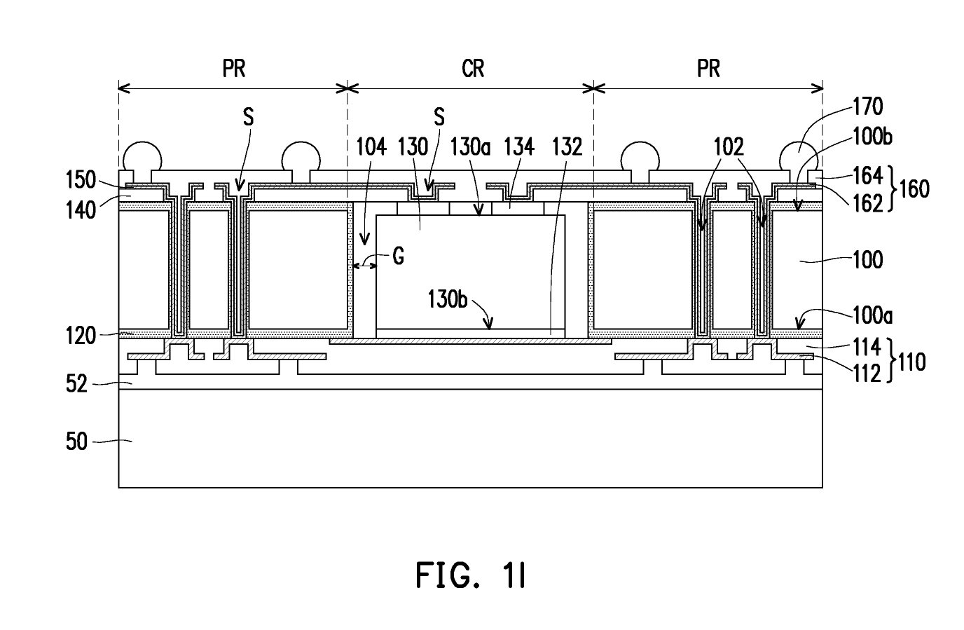

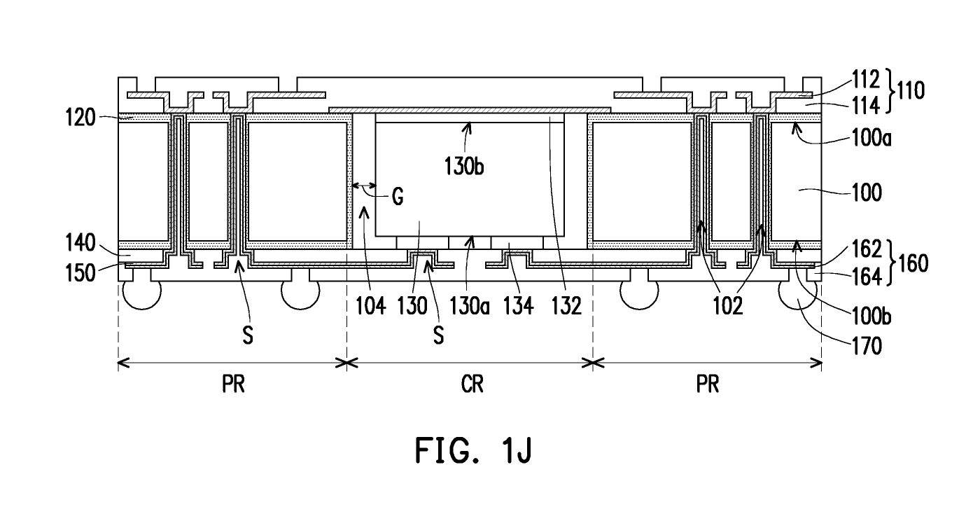

FIG. 1A to FIG. 1J are schematic cross-sectional views of a semiconductor package structure illustrating a manufacturing method of the said semiconductor package structure according to an embodiment of the disclosure. Referring to FIG. 1A, a semiconductor substrate 100 including a first surface 100a and a second surface 100b opposite to the first surface 100a is provided. The semiconductor substrate 100 may be, for example, a silicon wafer or a rigid substrate coated with silicon. Other suitable semiconductor substrate may be utilized as long as the coefficient of the thermal expansion (CTE) of the semiconductor substrate 100 may approximately match the CTE of a chip to be mounted in the subsequent process. The mismatch of CTEs may produce warpage stresses in the resulting package structure both during packaging and during operation of the finished device and may potentially delaminate the package structure or break electrical connections thereto. As such, using the semiconductor substrate having the CTE approximately matching the CTE of the chip, the warpage stress on the package structure caused by CTE mismatch between the semiconductor substrate and the chip may be substantially eliminated. In some embodiments, an insulating layer 120 may be formed on the first surface 100a of the semiconductor substrate 100. For example, the insulating layer 120 may be a silicon oxide layer or a silicon nitride layer formed by a chemical vapor deposition method. However, the material and the forming method of the insulating layer 120 construe no limitation in the disclosure as long as the insulating layer 120 may be utilized to electrically isolate the semiconductor substrate 100 for the subsequent processes.

A first redistribution layer 110 may be formed on the first surface 100a of the semiconductor substrate 100. In some embodiments, the first redistribution layer 110 may include a patterned conductive layer 112 and a dielectric layer 114. The patterned conductive layer 112 may be embedded in the dielectric layer 114, while a portion of dielectric layer 114 may be removed to expose at least a portion of the patterned conductive layer 112. For example, the dielectric layer 114 may be formed and patterned on the first surface 100a of the semiconductor substrate 100. Next, a conductive layer made of conductive materials such as copper, aluminum, nickel, or the like may be formed on the dielectric layer 114 by a sputtering process, an evaporation process, an electroplating process, or other suitable forming process. Subsequently, the conductive layer may be patterned by a photolithography and an etching process to form the patterned conductive layer 112. In some embodiments, the patterned conductive layer 112 may be formed before the dielectric layer 114. The forming sequence of the patterned conductive layer 112 and the dielectric layer 114 may depend on the design requirement, which is not limited thereto.

In some other embodiments, the aforementioned steps may be performed multiple times to obtain a multi-layered redistribution layer as required by the circuit design. The topmost dielectric layer 114 may have a plurality of openings (not illustrated) exposing at least the portion of the topmost patterned conductive layer 112.

Referring to FIG. 1B, a thickness of the semiconductor substrate 100 may be reduced using an etching process, a milling process, a mechanical grinding process, a chemical-mechanical polishing process, or other suitable thinning process, but is not limited thereto. In some embodiments, the thickness of the semiconductor substrate 100 may be already reduced when the semiconductor substrate 100 is provided. In some other embodiments, the first redistribution layer 110 may be disposed on a carrier 50 for supporting purpose. The carrier 50 may be made of glass, plastic, or other suitable materials as long as the material is able to withstand the subsequent processes while carrying the semiconductor package structure formed thereon. In some embodiments, a de-bonding layer 52 may be disposed between the carrier 50 and the first redistribution layer 110 to enhance the releasibility therebetween for the subsequent process. For example, the de-bonding layer 52 may be a LTHC (light to heat conversion) release layer or other suitable release layers. In some other embodiments, the first redistribution circuit layer 110 may be in contact with the carrier 50 directly.

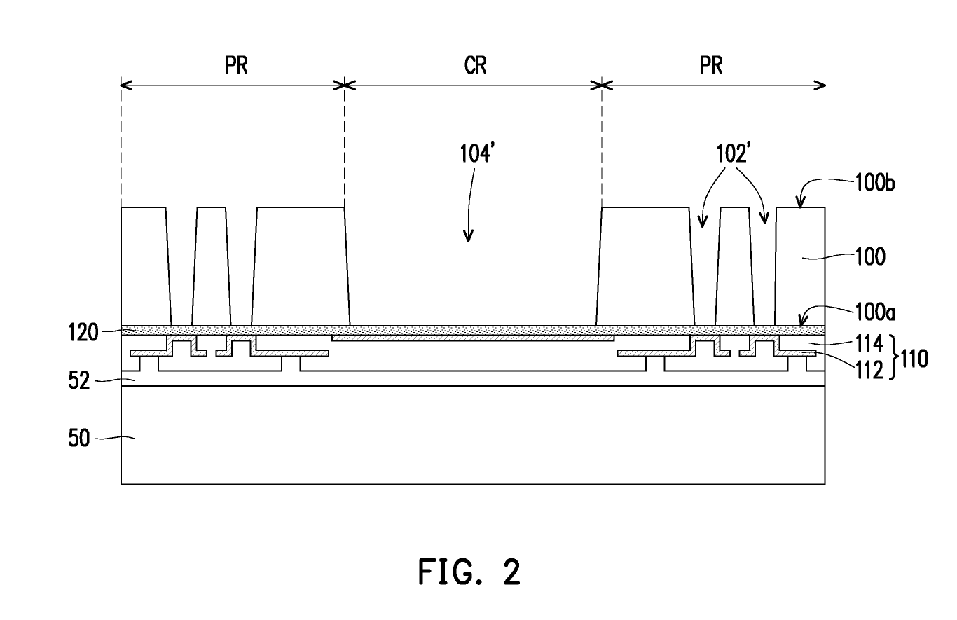

Referring to FIG. 1C, a plurality of through holes 102 and an opening 104 may be formed on the semiconductor substrate 100. For example, the semiconductor substrate 100 may include a central region CR and a peripheral region PR surrounding the central region CR. In some embodiments, the opening 104 may be formed in the central region CR and the through holes 102 may be formed in the peripheral region PR. For example, the through holes 102 and the opening 104 may be formed by a photolithography and an etching process to penetrate through the semiconductor substrate 100. In some embodiments, a laser drilling process, a mechanical drilling process or other suitable removing process may be performed to form the through holes 102 and the opening 104 through the semiconductor substrate 100. In some other embodiments, the through holes 102 and the opening 104 may be formed in the same process. The forming sequences of the through holes 102 and the opening 104 construe no limitation in the disclosure. In some embodiments, an inner surface (not illustrated) of the through holes 102 and/or an inner surface (not illustrated) of the opening 104 may be orthogonal to the first surface 100a of the semiconductor substrate 100. Referring to FIG. 2, similar with FIG. 1C, in some other embodiments, after forming the through holes 102′ and the opening 104′, the inner surface of the through holes 102′ and/or the inner surface of the opening 104′ may be tapered depending on the design requirements. In other word, the top width of each through hole 102′ may be wider than the bottom width (facing towards the first redistribution layer 110) of each through hole 102′ and/or the top width of the opening 104′ may be wider than the bottom width (facing towards the first redistribution layer 110) of the opening 104′.

Referring back to FIG. 1D, after forming the through holes 102 and the opening 104, the semiconductor substrate 100 may be electrically insulated. For example, the insulating layer 120 may be confonnally formed by a chemical vapor deposition process on the overall surface of the semiconductor substrate 100 for electrical isolation. In some embodiments, a portion of the insulating layer 120 may be removed by an anisotropic etching process to expose a portion of the patterned conductive layer 112 of the first redistribution layer 110 for further electrical connection. The patterned conductive layer 112 of the first redistribution layer 110 formed corresponding to the central region CR may serve as the etch-stop layer to avoid the dielectric layer 114 being over etched. In other word, the patterned conductive layer 112 exposed by the insulating layer 120 corresponding to the peripheral region PR may be used to further electrical connection, while the patterned conductive layer 112 exposed by the insulating layer 120 corresponding to the central region CR may serve as a dummy layer to prevent over-etching.

Referring to FIG. 1E, a chip 130 may be disposed in the opening 104 of the semiconductor substrate 100. The chip 130 may be, for example, a silicon chip (e.g. ASIC chip or MEMS chip). Other suitable active devices may also be utilized as the chip 130. In some embodiments, when forming the opening 104 in the central region CR of the semiconductor substrate 100 or removing a portion of the insulating layer 120 to expose the patterned conductive layer 112 corresponding to the central region CR, an alignment mark (not illustrated) for positioning of the chip 130 may be formed simultaneously on the semiconductor substrate 100. As such, the alignment mark enables the chip 130 to be positioned precisely in the opening 104 of the semiconductor substrate 100. In some embodiments, the chip 130 may include an active surface 130a and a back surface 130b opposite to the active surface 130a. In some other embodiments, the back surface 130b of the chip 130 may be adhered to the first redistribution layer 110 using an adhesive layer 132. For example, the adhesive layer 132 may include epoxy resin, inorganic materials, organic polymer materials, or other suitable adhesive materials. In some embodiments, the chip 130 may include a plurality of conductive bumps 134 disposed on the active surface 130a for transmitting the electrical signals of the chip 130. A material of the conductive bumps 134 may include copper, tin, gold, nickel, solder, or the combination thereof, but is not limited thereto. For example, the conductive bumps 134 may be reflowed solder bumps, conductive pillars (e.g. solder pillars, gold pillars, copper pillars or the like), or conductive studs. Other possible forms and shapes of the conductive bumps 134 may be utilized which construe no limitation in the disclosure.

In some embodiments, after disposing the chip 130 in the opening 104 of the semiconductor substrate 100, a gap G may be formed between the chip 130 and the semiconductor substrate 100 which may be covered by the insulating layer 120. In other word, the gap G may be defined as the remaining space of the opening 104 after disposing the chip 130. In some other embodiments, a filler (not illustrated) may be filled in the gap G to support to the chip 130. For example, a material of the filler may include polymeric material such as epoxy resin or acrylic resin, but is not limited thereto. In some embodiments, the CTE of the filler may range between the CTE of the chip 130 and the CTE of the semiconductor substrate 100 such that the shearing stress therebetween may be reduced. In some other embodiments, the filler may be thermally conductive for heat dissipation depending on the design requirements.

Referring to FIG. 1F, a tenting layer 140 may be formed on the second surface 100b of the semiconductor substrate 100 and the chip 130. For example, the tenting layer 140 may expose the through holes 102 and partially cover the chip 130. In some embodiments, the tenting layer 140 may include epoxy resin, organic polymer materials, or other suitable insulating materials which may have the ability to partially cover the insulating layer 140 on the semiconductor substrate 100 and the chip 130 without entering into the through holes 102 and the gap G. For example, a resin layer (e.g. a dry film) may be disposed on the top surface of the insulating layer 120 and the chip 130 using a photolithography and etching process to form the tenting layer 140 with a plurality of the openings corresponding to the through holes 102 of the semiconductor substrate 100. In some embodiments, the tenting layer 140 may include the openings in the central region CR exposing at least a portion of the conductive bumps 134 of the chip 130 for further electrical connection. In other word, the tenting layer 140 may partially cover the opening 104 of the semiconductor substrate 100 while exposing at least a portion of the conductive bumps 134 of the chip 130. In some other embodiments, when forming the through holes 102 of the semiconductor substrate 100, an alignment mark may be formed on the semiconductor substrate 100 simultaneously for positioning of the tenting layer 140.

Referring to FIG. 1G, a conductive through via 150 may be formed in the through holes 102 of the semiconductor substrate 100 to electrically connect the first redistribution layer 110. In some embodiments, the conductive through via 150 may be a conductive layer conformally formed on the tenting layer 140 and in the through holes 102 of the semiconductor substrate 100 using a sputtering method, an evaporation method, an electroplating method, or other suitable method. For instance, the conductive layer may be conformally formed in the inner surface of the through holes 102, extending onto the top surface of the tenting layer 140, and further to the openings of the tenting layer 140 where the conductive bumps 134 of the chip 130 are exposed. As such, the conductive through via 150 may electrically connect between the chip 130 and the patterned conductive layer 112 of the first redistribution layer 110. In some embodiments, since the conductive layer 112 may be conformally deposited in the inner surface of the through holes 102 and/or the openings of the tenting layer 140. A space S may be formed in the conductive through via 150 corresponding to the through holes 102 and/or the opening of the tenting layer 140. Thus, the manufacturing cost and saving the process time may be effectively lowered. In other word, the through holes 102 may not be filled with the conductive through via 150 in such embodiments. In some other embodiments, the conductive through via 150 may be formed as a conductive pillar filling in the through holes 102 of the semiconductor substrate 100.

Referring to FIG. 1H, a second redistribution layer 160 may be formed on the second surface 100b of the semiconductor substrate 100 to electrically connect the chip 130 and the first redistribution layer 110 through the conductive through vias 150. The second redistribution layer 160 may include a patterned conductive layer 162 and a dielectric layer 164. For example, a patterned resist layer (not illustrated) may be formed on the conductive through vias 150 corresponding to the tenting layer 140 and a conductive material may be conformally formed along with the conductive through vias 150. Subsequently, the patterned resist layer may be removed to form the patterned conductive layer 162. Next, the dielectric layer 164 may be formed on the patterned conductive layer 162 and expose at least a portion of the patterned conductive layer 162 to form the second redistribution layer 160. In some embodiments, before forming the dielectric layer 164, a portion of the conductive through via 150 extending onto the top surface of the tenting layer 140 may be removed using an etching process. In some other embodiments, the dielectric layer 164 may fill into the space S corresponding to the peripheral region PR and/or the central region CR depending on the material characteristic of the dielectric layer 164. It should be noted that the forming processes of the patterned conductive layer 162 and the dielectric layer 164 may be performed multiple times to obtain a multi-layered redistribution circuit layer as required by the circuit design. The topmost dielectric layer 164 may have openings (not illustrated) exposing at least the portion of the topmost patterned conductive layer 162 for further electrical connection. In some embodiments, the portion of the patterned conductive layer 162 exposed by the dielectric layer 164 may be referred as under-ball metallurgy (UBM) patterns for the subsequent ball-mount process.

Referring to FIG. 1I, a plurality of conductive structures 170 may be formed corresponding to the openings of the dielectric layer 164 to electrically connect the patterned conductive layer 162 of the second redistribution layer 160. For example, a material of the conductive structures 170 may include tin, lead, copper, gold, nickel, a combination thereof, or other suitable conductive materials. In some embodiments, the conductive structures 170 may be formed by a ball placement process, an electroless-plating process or other suitable processes. The conductive structures 170 may include conductive pillars, conductive bumps, solder balls or a combination thereof. However, the material and the forming process of the conductive structures 170 construe no limitation in the disclosure. Other possible forms and shapes of the conductive structures 170 may be utilized according to the design requirement. In some embodiments, a soldering process and a reflowing process may be optionally performed for enhancement of the adhesion between the conductive structures 170 and the second redistribution circuit layer 160.

Referring to FIG. 1J, after forming the conductive structure 170, the carrier 50 may be removed from the first redistribution layer 110 to form a semiconductor package structure 10. For example, the external energy such as UV laser, visible light or heat, may be applied to the de-bonding layer 52 so that the first redistribution layer 110 may be peeled off from the carrier 50. In some embodiments, after removing the carrier 50, the patterned conductive layer 112 may be exposed by the dielectric layer 114 of the first redistribution layer 110 for external electrical connection.

Based on the foregoing, the chip is disposed in the opening of the semiconductor substrate such that the semiconductor substrate may serve as the encapsulant to protect the chip. As such, the conventional molding process may be omitted. Moreover, the semiconductor substrate may minimize effects of the CTE mismatch between the chip and the semiconductor substrate and the warpage issue therebetween may be eliminated. In addition, when forming the opening and the through holes of the semiconductor substrate, the alignment mark for positioning of the chip and the tenting layer may be formed simultaneously on the semiconductor substrate, thereby increasing the reliability of the semiconductor package structure with simplified manufacturing process. Furthermore, the conductive through via formed in the through holes may serve as the conductive path between the first redistribution layer and the second redistribution layer. Therefore, miniaturizing the semiconductor package structure while maintaining the process simplicity may be achieved.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

1. A manufacturing method of a semiconductor package structure, comprising:
forming a first redistribution layer on a first surface of a semiconductor substrate;
forming a plurality of through holes and an opening on the semiconductor substrate;
forming an insulating layer on the semiconductor substrate after forming the plurality of through holes and the opening;
disposing a chip in the opening of the semiconductor substrate;
forming a conductive through via in each of the through holes of the semiconductor substrate to electrically connect to the first redistribution layer, wherein after forming the conductive through via, the insulating layer is between the conductive through via and the semiconductor substrate to electrically isolate the semiconductor substrate from the conductive through via;
forming a second redistribution layer on a second surface of the semiconductor substrate opposite to the first surface to electrically connect to the chip, wherein the second redistribution layer is electrically connected to the first redistribution layer through the conductive through via; and
forming a plurality of conductive structures on the second redistribution layer.

2. The manufacturing method according to claim 1 further comprising reducing a thickness of the semiconductor substrate before forming the plurality of through holes and the opening on the semiconductor substrate.

3. (canceled)

4. The manufacturing method according to claim 1, wherein the first redistribution layer comprises a patterned conductive layer, a portion of the insulating layer is removed to expose at least a portion of the patterned conductive layer before disposing the chip.

5. The manufacturing method according to claim 1, wherein the chip is adhered to the first redistribution layer using an adhesive layer.

6. The manufacturing method according to claim 1, wherein after disposing the chip in the opening of the semiconductor substrate, a gap is formed between the chip and the semiconductor substrate.

7. The manufacturing method according to claim 1, wherein the semiconductor substrate comprises a central region and a peripheral region surrounding the central region, the opening is formed in the central region and the plurality of through holes are formed in the peripheral region.

8. The manufacturing method according to claim 1, wherein a space is formed in the conductive through via after forming the conductive through via in each of the through holes.

9. The manufacturing method according to claim 1, wherein the conductive through via is formed as a conductive pillar filling in each of the through holes.

10. The manufacturing method according to claim 1 further comprising forming a tenting layer on the second surface of the semiconductor substrate and on the chip before forming the conductive through via, wherein the tenting layer exposes the plurality of through holes and partially covers the chip.

11. A semiconductor package structure, comprising:
a semiconductor substrate, comprising a first surface and a second surface opposite to the first surface, wherein the semiconductor substrate comprises a plurality of through holes and an opening, and the plurality of through holes and the opening penetrate through the semiconductor substrate;
a chip disposed in the opening of the semiconductor substrate;
a first redistribution layer disposed on the first surface of the semiconductor substrate;
a second redistribution layer disposed on the second surface of the semiconductor substrate, wherein the second redistribution layer is electrically connected to the chip;
a conductive through via disposed in each of the through holes of the semiconductor substrate, wherein the first redistribution layer is electrically connected to the second redistribution layer by the conductive through via;
a plurality of conductive structures disposed on the second redistribution layer; and
an insulating layer, disposed between the conductive through via and the semiconductor substrate to electrically isolate the semiconductor substrate from the conductive through via.

12. (canceled)

13. The semiconductor package structure according to claim 11, wherein the first redistribution layer comprises a patterned conductive layer, at least a portion of the patterned conductive layer is electrically connected to the conductive through via.

14. The semiconductor package structure according to claim 11 further comprising:
an adhesive layer, disposed between the first redistribution layer and the chip.

15. The semiconductor package structure according to claim 11, wherein a gap is disposed between the chip and the semiconductor substrate corresponding to the opening, a filler is disposed in the gap.

16. The semiconductor package structure according to claim 11, wherein the semiconductor substrate comprises a central region and a peripheral region surrounding the central region, the opening is disposed in the central region and the plurality of through holes are disposed in the peripheral region.

17. The semiconductor package structure according to claim 11, wherein the conductive through via is disposed in each of the through holes of the semiconductor substrate.

18. The semiconductor package structure according to claim 11, wherein the conductive through via comprises a conductive pillar disposed in each of the through holes of the semiconductor substrate.

19. The semiconductor package structure according to claim 11, further comprising:
a tenting layer, disposed on the second surface of the semiconductor substrate and the chip, wherein the tenting layer partially covers the semiconductor substrate and the chip.

20. The semiconductor package structure according to claim 11, wherein the chip comprises a plurality of conductive bumps, the second redistribution layer is electrically connected to the chip by the plurality of conductive bumps.
